(19) United States
(12) Patent Application Publication
(10) Pub. No.: US 2025/0106993 A1
(43) Pub. Date: Mar. 27, 2025

(54) CIRCUIT CARRIER AND METHOD

(71) Applicant: Vitesco Technologies GmbH, Regensburg (DE)

(72) Inventor: Detlev BAGUNG, Bernhardswald (DE)

(73) Assignee: Vitesco Technologies GmbH, Regensburg (DE)

(21) Appl. No.: 18/889,569

(22) Filed: Sep. 19, 2024

(30) Foreign Application Priority Data
Sep. 21, 2023 (DE) 10 2023 209 201.8

(51) Int. Cl. H05K 1/05; H05K 3/46

(52) U.S. Cl. CPC H05K 1/05; H05K 3/4644; H05K 2201/0104

(57) ABSTRACT

A circuit carrier for at least one electrical component, including: a metal substrate layer, a first electrical insulation layer arranged on the metal substrate layer, a second electrical insulation layer arranged on the first insulation layer, and an electrically conductive layer, arranged on the second electrical insulation layer, having at least one conductor track for electrically connecting the at least one electrical component, wherein at least one of the two electrical insulation layers is colored in such a way that the two electrical insulation layers have different colors.

### CROSS REFERENCE TO RELATED APPLICATIONS

This application claims priority to German Patent Application No. 10 2023 209 201.8, filed Sep. 21, 2023, the contents of such application being incorporated by reference herein.

### FIELD OF THE INVENTION

The present invention relates to a circuit carrier, in particular a circuit carrier designed as an insulated metal substrate printed circuit board. The present invention furthermore relates to a method for producing a circuit carrier. The present invention furthermore relates to a method for ascertaining a number of insulation layers in a circuit carrier.

### BACKGROUND OF THE INVENTION

Circuit carriers and in particular circuit carriers having a metal substrate layer, as is present, for example, in an insulated metal substrate printed circuit board, have to satisfy a variety of requirements. One example of a requirement important in particular in the automotive field is sufficient insulation of the mentioned metal substrate layer in relation to electrical components electrically connected to the circuit carrier. In particular in the area of quality management and/or component testing, there are strict regulations in the area of insulation which have to be complied with.

### SUMMARY OF THE INVENTION

An aspect of the present invention is a circuit carrier which satisfies high requirements for the insulation capacity of electrical components mounted on this circuit carrier. Furthermore, it is an object of the present invention to provide a method for producing such a circuit carrier. Furthermore, an aspect of the present invention is a method for ascertaining a number of insulation layers in a circuit carrier.

According to a first aspect of the present invention, a circuit carrier is provided, in particular a circuit carrier designed as an insulated metal substrate printed circuit board for at least one electrical component. The circuit carrier comprises: a metal substrate layer, a first electrical insulation layer arranged on the metal substrate layer, a second electrical insulation layer arranged on the first electrical insulation layer, and an electrically conductive layer arranged on the second electrical insulation layer, wherein the electrically conductive layer comprises at least one conductor track for electrically connecting the at least one electrical component. In the circuit carrier according to an aspect of the invention, at least one of the two electrical insulation layers is colored such that the two electrical insulation layers have different colors.

The circuit carrier according to an aspect of the invention is based at least partially on the finding that the most recent requirements in the area of the electrical installation of circuit carriers comprising a metal substrate layer require at least two unambiguously identifiable electrical insulation layers which are applied to the metal substrate layer. The circuit carrier according to the first aspect is at least partially based on the finding that these requirements can be met if the two insulation layers applied directly one on top of the other have different colors. Due to the different colors, the electrical insulation layers can be unambiguously identified and the number of the electrical insulation layers can be ascertained. The circuit carrier according to an aspect of the invention therefore comprises at least one electrically insulated insulation layer, which is colored such that the two electrical insulation layers have different colors after the coloration. The concept is based on the finding that with insulation layers applied directly one on top of the other, in some circumstances it is not possible to recognize the two insulation layers arranged adjacent to one another as such. However, due to the different colors, it is possible to establish the number of the electrical insulation layers unambiguously and unequivocally. This identification and/or ascertainment of the number of insulation layers can take place, for example, in the context of a test which is to be carried out for the release of the circuit carrier.

In one advantageous embodiment, at least one of the two insulation layers is colored in such a way that the two insulation layers are recognizable as two distinct or delimited insulation layers at least in a cross section, in particular a micro section, of the circuit carrier due to their different colors. This preferred embodiment is at least partially based on the finding that a micro section of the circuit carrier is typically produced to determine and/or assess a layered structure of such circuit carriers. Producing a micro section can require, for example, exposing a cross-sectional surface, in particular a full cross section of the circuit carrier. The exposed cross-sectional surface can then be prepared (for example, ground and/or polished), in order to be able to carry out the assessment of the number of layers and possibly a layer thickness of the layers in a circuit carrier prepared in this manner. Because, according to the preferred embodiment, at least one of the two insulation layers is colored in such a way that the two insulation layers are recognizable as two distinct insulation layers at least in the cross section of the circuit carrier due to their different colors, it is possible, for example, upon, during, or after the creation of a micro section to ascertain a number of insulation layers in the circuit carrier by counting the different colored insulation layers. The coloration of at least one of the two insulation layers can take place in such a way that at least in cross section, in particular in the micro section of the circuit carrier, edges of the respective insulation layer and/or a full cross section of the respective insulation layer are or is unambiguously identifiable.

It is particularly advantageous if at least one of the two insulation layers is colored in such a way that the two distinct insulation layers are recognizable with the naked eye. In other words, at least one of the two insulation layers is colored in such a way that the color of this insulation layer is in the visible color spectrum. This particularly preferred embodiment enables the identification of a number of distinct or delimited insulation layers with the naked human eye, i.e. without the aid of further testing materials and/or testing devices such as an IR camera or the like. In other words, this preferred embodiment provides that at least one of the two electrical insulation layers is colored such that the color of the colored insulation layer is in a range visible to the human eye, for example, in the visible light spectrum or color spectrum or in the visible component of the electromagnetic spectrum.

A further preferred embodiment provides that the electrical insulation layers are colored using varicolored particles. It is easy in particular in the production process to provide different colored insulation layers due to the use of varicolored particles.

In a further advantageous embodiment, the circuit carrier according to an aspect of the invention furthermore comprises: a further, in particular third insulation layer, which is arranged on the electrically conductive layer, a further, in particular fourth electrical insulation layer, which is arranged on the third insulation layer, and a further, in particular second electrically conductive layer, which is arranged on the further, in particular fourth electrical insulation layer and comprises at least one further electrical conductor track for electrically connecting the at least one electrical component. By providing further, in particular third and fourth electrical insulation layers on the electrically conductive layer and a further, in particular second electrically conductive layer on the fourth insulation layer, it is possible to connect at least one electrical component to one and/or two electrically conductive layers. The wiring possibilities are thus increased. This can be advantageous in particular in the case of multiple components on the circuit carrier.

The third insulation layer and/or the fourth insulation layer is preferably colored in such a way that the two electrical insulation layers, thus the third and fourth insulation layer or in more general terms the insulation layers lying directly one on top of another, have different colors. The colors of the third and/or fourth insulation layer can be the same or a different color as the first or second insulation layer.

According to a second aspect of the present invention, a method is provided for producing a circuit carrier for at least one electrical component, wherein the method comprises the following steps: providing a metal substrate layer; applying a first electrical insulation layer to the metal substrate layer; applying a second electrical insulation layer to the first electrical insulation layer; and applying an electrically conductive layer to the second electrical insulation layer, wherein the electrically conductive layer comprises at least one conductor track for electrically connecting the at least one electrical component and wherein at least one of the two electrical insulation layers is colored in such a way that the two electrical insulation layers have different colors.

In one preferred embodiment of the method according to an aspect of the invention, the coloration takes place before the application of the corresponding insulation layer, during the application of the corresponding insulation layer, or after the application of the corresponding insulation layer. For example, the corresponding electrical insulation layer can be immersed in paint before the application. For example, the electrical insulation layer can be colored during the application by adding colored particles to the material composition of the insulation layer, such as a plastic suspension, during the application of the electrical insulation layer. The corresponding insulation layer can also be colored after the application, however, for example, by immersing a pre-assembly and/or the entire circuit carrier in a colored solution, which has the result that at least the corresponding electrical insulation layer is colored and in this way has a different color than the other electrical insulation layer.

In a further preferred embodiment, the coloration is carried out in such a way that the two insulation layers are recognizable as two distinct or delimited insulation layers at least in a cross section, in particular a micro section of the circuit carrier, due to their different colors.

A further preferred embodiment of the method according to an aspect of the invention furthermore comprises the following steps: Applying a further, in particular third electrical insulation layer to the electrically conductive layer, applying a further, in particular fourth electrical insulation layer to the third insulation layer, and applying a further, in particular second electrically conductive layer to the further, in particular fourth electrical insulation layer, wherein the further, in particular second electrically conductive layer also comprises at least one conductor track for electrically connecting the at least one electrical component. Using this preferred embodiment of the method according to an aspect of the invention, in particular multiple electrical components can be electrically connected to the first and/or second electrical layer, by which the wiring possibilities are increased.

The third and/or fourth electrical insulation layer is preferably colored in such a way that the two electrical insulation layers, thus the third and fourth insulation layer or in general terms the insulation layers lying directly one on top of another, have different colors.

According to a third aspect of the present invention, a method for ascertaining a number of insulation layers in a circuit carrier, in particular in a circuit carrier according to the first aspect and/or embodiments thereof, is provided, wherein the method comprises the following steps: Preparing a cross section, in particular a micro section, of the circuit carrier, and ascertaining the number of insulation layers in the circuit carrier on the basis of different colors of the insulation layers.

In a preferred embodiment of the method according to the third aspect, the step of preparing a micro section of the circuit carrier comprises the following steps: Exposing a cross-sectional surface, in particular a full cross section of the circuit carrier, for example, by means of an angle grinder, and preparing the cross-sectional surface to ascertain the number of insulation layers, for example, by grinding and/or polishing the cross-sectional surface.

In a further preferred embodiment of the method according to the third aspect, to ascertain the number of insulation layers in the circuit carrier, the circuit carrier or at least one insulation layer of the circuit carrier is colored, in particular colored in such a way that the colored insulation layer has a different color than the other insulation layer in particular lying directly above it or directly below it.

In a further preferred embodiment of the method according to the third aspect, the coloration takes place before or after the preparation of the cross section, in particular before or after the preparation of the micro section of the circuit carrier.

### BRIEF DESCRIPTION OF THE DRAWINGS

Further features and aspects of the present invention will become apparent to a person skilled in the art by practicing the present teaching and taking into consideration the accompanying drawings. In the figures:

FIG. 1 shows a schematic view of a layered structure of a circuit carrier according to an aspect of the invention having two electrical insulation layers arranged one on top of the other and directly adjacent, which have different colors.

FIG. 2 shows a schematic view of a layered structure of an embodiment of the circuit carrier according to an aspect of the invention having two different colored electrical insulation layers and a further third and fourth insulation layer and a further second electrical layer for connecting an electrical component.

FIG. 3 shows a schematic view of a flow chart for carrying out a method for producing a circuit carrier according to an aspect of the invention.

FIG. 4 shows a schematic view of a flow chart for carrying out a method for ascertaining a number of electrical insulation layers in a circuit carrier according to an aspect of the invention.

Elements of the same design or function are provided with the same reference signs throughout the figures.

### DETAILED DESCRIPTION OF EXEMPLARY EMBODIMENTS

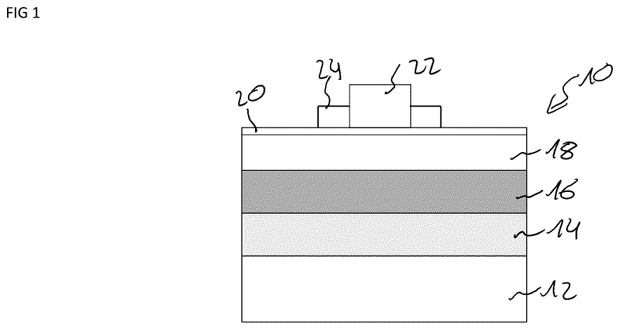

Reference is first made to FIG. 1, which shows a schematic view of a layered structure of a circuit carrier 10. The circuit carrier 10 can be, for example, an insulated metal substrate layer printed circuit board (IMS printed circuit board).

The circuit carrier 10 comprises a metal substrate layer 12, which consists of aluminum, copper, another metal, or another metal alloy. The metal substrate layer 12 is electrically conductive due to the metal component in the metal substrate layer 12. The metal substrate layer 12 is distinguished by a particularly high thermal conductivity, however, and can be connected in a heat-conductive manner to a heat sink (not shown), for example, which is advantageous in particular in the heat dissipation of high-performance components.

The circuit carrier 10 comprises a first electrical insulation layer 14 arranged on or applied to the metal substrate layer 12. The circuit carrier 10 comprises a second electrical insulation layer 16 applied to or arranged on the first electrical insulation layer 14. The two electrical insulation layers 14, 16 can be formed from an electrical insulation material such as plastic, ceramic, resin, or the like. The electrical insulation layers 14, 16 are used for the electrical insulation in relation to the metal substrate layer 12. The electrical insulation layers 14, 16 are applied directly to one another. In other words, no further layers are located between the first electrical insulation layer 14 and the second electrical insulation layer 16. In still other words, an upper side of the first electrical insulation layer 14 contacts a lower side of the second electrical insulation layer 16.

The circuit carrier 10 furthermore comprises an electrically conductive layer 18 applied to or arranged on the second electrical insulation layer 16. The electrically conductive layer 18 comprises at least one conductor track. An electrical component 22, which is electrically connected to the conductor track 20 of the electrically conductive layer 18, is arranged on the electrically conductive layer 18. In the specific example of FIG. 1, the electrical connection is produced by means of a bond wire 24. In other embodiments (not shown), the electrical connection can obviously be produced by other means.

As schematically shown in FIG. 1, the two electrical insulation layers 14, 16 differ due to their colors. This is schematically shown on the basis of a first electrical insulation layer marked light gray and a second electrical insulation layer marked dark gray. Of course, the colors of the electrical insulation layers can be arbitrary and are not restricted to the colors shown in FIG. 1.

In the circuit carrier 10 according to an aspect of the invention, at least one of the two electrical insulation layers 14, 16 is colored in such a way that the two electrical insulation layers 14, 16 arranged directly one on top of the other are recognizable as two distinct insulation layers 14, 16 on the basis of their different coloration or colors. The two insulation layers 14, 16 can accordingly thus be distinguished on the basis of their color or coloration.

The schematic layered structure shown in FIG. 1 can be made visible, for example, by means of a cross section through the circuit carrier 10, in particular by means of a micro section of the circuit carrier 10. The micro section is produced, for example, in that the circuit carrier 10 is cut through, for example, by means of an angle grinder, and a cross-sectional surface is exposed, in particular a full cross section of the circuit carrier 10. The exposed cross-sectional surface can then be prepared, for example, by means of grinding and/or polishing. The two electrical insulation layers 14, 16 are recognizable in the cross section or micro section as two distinct insulation layers 14, 16. In particular, at least one electrical insulation layer 14, 16 can be colored in such a way that the different insulation layers are recognizable with the naked eye, i.e. without the aid of technical means (cameras, etc.), on the basis of their different colors. When the circuit carrier 10 is examined, for example, in the context of a quality control or in the context of a checking method, the number of the insulation layers 14, 16 (in the specific example of FIG. 1 “two”) can be ascertained with the naked eye.

The coloration of at least one of the two electrical insulation layers 14, 16 can take place before, during, or after the application of the corresponding electrical insulation layer 14, 16. The coloration of at least one of the two electrical insulation layers 14, 16 can take place before or after the preparation of the cross section or micro section.

The specific example of FIG. 1 shows that the entire cross section of the respective insulation layer 14, 16 is colored. However, it is sufficient in the scope of the present disclosure if only the contour edges of a respective electrical insulation layer have different colors. For example, it is conceivable that before, during, or after the application of the corresponding electrical insulation layer 14, 16, the respective insulation layer 14, 16 is colored in such a way that only the contour of the respective insulation layer 14, 16 appears to be a different color, so that the number of discrete insulation layers is thus ascertainable.

The coloration of at least one of the two electrical insulation layers 14, 16 lying directly one on top of the other can be carried out, for example, by introducing colored particles into the corresponding insulation layer 14, 16. The introduction of colored particles can take place before, during, or after the application of the corresponding insulation layer 14, 16. For example, it is conceivable that first the corresponding insulation layer 14, 16 is produced, then it is colored, for example, by immersion in a color solution, and then the colored insulation layer is applied. Alternatively or additionally, during the application of the insulation layer, colored particles can be introduced into a material suspension, for example, a plastic suspension, so that a colored plastic suspension can be applied and accordingly the coloration of the insulation layer 14, 16 takes place during the application of the suspension. Alternatively or additionally, it is also possible that after the application of the corresponding insulation layer, it is colored. For example, this can be carried out by immersing a preassembly of the circuit carrier 10 or the entire circuit carrier 10 in a color solution, in particular after exposing the cross section or micro section.

Arbitrary further possibilities for the colored coloration to identify the corresponding number of insulation layers in the circuit carrier 10 are conceivable.

The corresponding insulation layer 14, 16 is advantageously colored in such a way that the insulation layers 14, 16 are recognizable with the naked eye on the basis of their different colors. A color is advantageously selected which is in the visible light spectrum or color spectrum or in a component of the electromagnetic spectrum which is recognizable with the human eye.

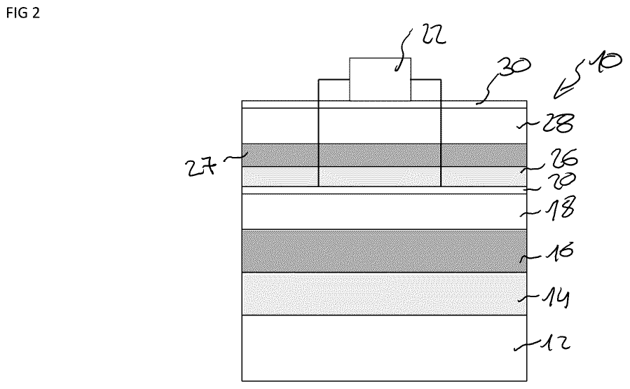

Reference will now be made to FIG. 2, which shows a schematic view of a layered structure of an embodiment of the circuit carrier 10 from FIG. 1.

In the embodiment of FIG. 2, the circuit carrier comprises the metal substrate layer 12, the first electrical insulation layer 14, and the second electrical insulation layer 16, which is applied directly to the first insulation layer 14 and differs in color (due to its coloration) from the first electrical insulation layer 14. The circuit carrier 10 of FIG. 2 comprises a first electrically conductive layer 18 having a conductor track 20, which is used for connecting the electrical component 22. In contrast to the embodiment of the circuit carrier 10 from FIG. 1, in the embodiment of FIG. 2, a further, in particular third electrical insulation layer 26 and a further, in particular fourth electrical insulation layer 27 are applied to the first electrically conductive layer. The third electrical insulation layer 26 and/or the fourth insulation layer 27 can have the same or a different color as the two first electrical insulation layers 14, 16. The third insulation layer 26 and/or the fourth insulation layer 27 may also be colored or may not be colored. Preferably, the third and/or fourth insulation layer 26, 27 are colored in such a way that the two insulation layers 26, 27—similarly as in the insulation layers 14, 16—are recognizable as two distinct insulation layers, in particular at least in a cross section and/or micro section of the circuit carrier 10.

In the embodiment of FIG. 2, a further, in particular second electrically conductive layer 28 is arranged on the fourth electrical insulation layer 27. The second electrically conductive layer 28 comprises at least one further conductor track 30, which can be used for electrically connecting the electrical component 22. By means of the second electrically conductive layer 28, the electrical component 22 can be connected not only to the conductor track 20 of the first electrical layer 18 but also to the conductor track 30 of the second electrical layer 28. Depending on the application, the electrical component 22 can be connected here to the first electrically conductive layer 18 and/or the second electrically conductive layer 28. The third and fourth electrical insulation layers 26, 27 are used for electrical insulation. The third and fourth electrical insulation layers 26, 27 and the second electrically conductive layer 28 are helpful in particular in the electrical connection of multiple components 22 to the circuit carrier 10, since in this way the wiring possibilities increase with a sufficiently high level of insulation.

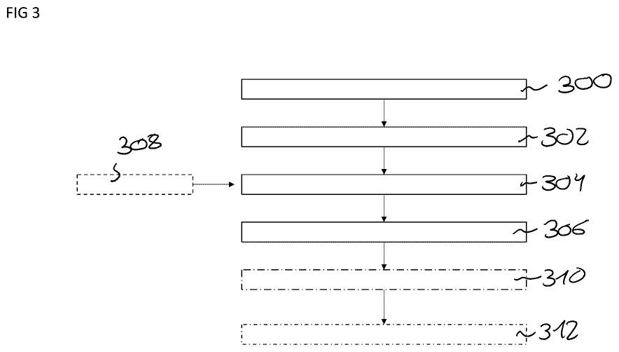

Reference is now made to FIG. 3, which shows a schematic view of a flow chart for carrying out a method for producing a circuit carrier, such as the circuit carrier 10 described in conjunction with FIGS. 1 and 2.

The method comprises a step 300, in which a metal substrate layer is provided, such as the metal substrate layer 12 mentioned in conjunction with FIGS. 1 and 2. In a step 302, a first electrical insulation layer, such as the first electrical insulation layer 14 mentioned in conjunction with FIGS. 1 and 2, is applied to the metal substrate layer. In a step 304, a second electrical insulation layer, such as the second electrical insulation layer 16 mentioned in conjunction with FIGS. 1 and 2, is applied to the first electrical insulation layer. In a step 306, an electrically conductive layer, such as the electrically conductive layer 18 mentioned in conjunction with FIGS. 1 and 2, is applied to the second electrical insulation layer. In the method shown in FIG. 3, at least one of the two electrical insulation layers is now colored in such a way that the two electrical insulation layers have different colors and can thus be distinguished from one another, in particular in a cross section or micro section of the circuit carrier. The coloration of at least one of the electrical insulation layers is schematically indicated in FIG. 3 by a dashed step 308. The dashed step 308 is supposed to show that in the specific example of FIG. 3, the second electrical insulation layer which is applied in step 304 is colored. It is not important whether this coloration takes place before, during, or after the application of the layer.

Of course, it is also conceivable that in other embodiments (not shown), the first electrical insulation layer and/or the second electrical insulation layer are colored. In such a case, the method would have an additional step in which the corresponding first or second insulation layer is also colored. Coloration of the first insulation layer can take place at the same time as, before, or after the coloration of the second insulation layer. It is essential that after the coloration, both insulation layers arranged directly one on top of the other have different colors.

In the specific example of FIG. 3, moreover two further optional method steps are indicated by means of dot-dash boxes. It is thus conceivable that after the application of the first electrically conductive layer (step 306), a further step 310 takes place, in which a further, in particular third and fourth electrical insulation layer, such as the third and fourth insulation layers 26, 27 mentioned in conjunction with FIG. 2, are applied to the first electrically conductive layer. In a step 312 following step 310, a further, in particular second electrically conductive layer, such as the electrically conductive layer 28 mentioned in conjunction with FIG. 2, can be applied to the fourth electrical insulation layer 27. This increases the wiring possibilities in the electrical connection of electrical components to the circuit carrier. The third and/or fourth insulation layer can be colored, at least in such a way that the two insulation layers are recognizable as two distinct insulation layers at least in a cross section or micro section of the circuit carrier due to their different colors.

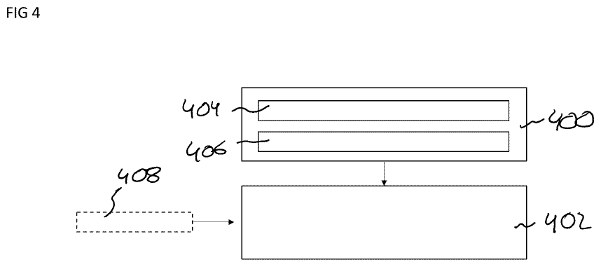

Reference will now be made to FIG. 4, which shows a schematic view of a flow chart for carrying out a method for ascertaining a number of electrical insulation layers in a circuit carrier, such as the circuit carrier 10 which was described in conjunction with FIGS. 1 and 2.

In the method according to FIG. 4, in a step 400, a cross section, in particular a micro section of the circuit carrier is produced. In a step 402, the number of insulation layers in the circuit carrier is then ascertained on the basis of different colors of the insulation layers in the cross section or micro section.

The production of a micro section can comprise further steps here, thus, for example, a step 404 in which a cross-sectional surface, in particular a full cross section of the circuit carrier is exposed, and a step 406, in which the exposed cross-sectional surface is prepared to ascertain the number of insulation layers. The preparation can comprise grinding, polishing, or the like.

The ascertainment of the number of insulation layers in the circuit carrier on the basis of different colors (step 402) can comprise a step 408 here, in which at least one of the insulation layers of the circuit carrier lying directly one on top of another is colored, so that the number of insulation layers lying directly one on top of another is determinable on the basis of the different colors. The coloration preferably takes place before or after the preparation of the cross section or micro section. The coloration preferably takes place in such a way that the different colors of the insulation layers are recognizable with the naked eye.

The features of the circuit carrier 10 described in conjunction with FIGS. 1 and 2 can be implemented in corresponding steps of the method according to FIG. 3 and/or FIG. 4.

1. A circuit carrier for at least one electrical component, comprising:
a metal substrate layer,
a first electrical insulation layer arranged on the metal substrate layer,
a second electrical insulation layer arranged on the first insulation layer, and
an electrically conductive layer, arranged on the second electrical insulation layer, having at least one conductor track for electrically connecting the at least one electrical component, wherein
at least one of the two electrical insulation layers is colored in such a way that the two electrical insulation layers have different colors.

2. The circuit carrier as claimed in claim 1, wherein at least one of the two electrical insulation layers is colored in such a way that the two electrical insulation layers are recognizable as two distinct insulation layers at least in a cross section, in particular a micro section of the circuit carrier due to their different colors.

3. The circuit carrier as claimed in claim 2, wherein at least one of the two insulation layers is colored in such a way that the two distinct insulation layers are recognizable with the naked eye.

4. The circuit carrier as claimed in claim 1, wherein the electrical insulation layers are colored using varicolored particles.

5. The circuit carrier as claimed in claim 1, wherein at least one of the two electrical insulation layers is colored in such a way that the color of the colored insulation layer is in a range visible to the human eye.

6. The circuit carrier as claimed in claim 1, furthermore comprising:
a further, in particular third electrical insulation layer, which is arranged on the electrically conductive layer,
a further, in particular fourth electrical insulation layer, which is arranged on the third insulation layer, and
a further, in particular second electrically conductive layer, which is arranged on the fourth electrical insulation layer and comprises at least one further electrical conductor track for electrically connecting the at least one electrical component.

7. The circuit carrier as claimed in claim 6, wherein the third insulation layer and/or the fourth insulation layer are/is colored in such a way that the two electrical insulation layers have different colors.

8. A method for producing a circuit carrier for at least one electrical component (22), comprising:
providing a metal substrate layer,
applying a first electrical insulation layer to the metal substrate layer,
applying a second electrical insulation layer to the first electrical insulation layer, and
applying an electrically conductive layer to the second electrical insulation layer, wherein the electrically conductive layer comprises at least one conductor track for electrically connecting the at least one electrical component, and wherein
at least one of the two electrical insulation layers is colored in such a way that the two electrical insulation layers have different colors.

9. The method as claimed in claim 8, wherein the coloration takes place before the application, during the application, or after the application of the respective electrical insulation layer.

10. The method as claimed in claim 8, wherein the coloration takes place in such a way that the two insulation layers are recognizable as two distinct insulation layers at least in a cross section, in particular a micro section, of the circuit carrier due to their different colors.

11. The method as claimed in claim 8, furthermore comprising:
applying a further, in particular third electrical insulation layer to the electrically conductive layer,
applying a further, in particular fourth electrical insulation layer to the third insulation layer,
applying a further, in particular second electrically conductive layer having a conductor track for electrically connecting the at least one electrical component to the fourth electrical insulation layer, and
coloring the third and/or fourth insulation layer in such a way that the two electrical insulation layers have different colors.

12. A method for ascertaining a number of insulation layers in a circuit carrier, in particular in a circuit carrier as claimed in claim 1, comprising:
preparing a cross section, in particular a micro section, of the circuit carrier, and
ascertaining the number of insulation layers in the circuit carrier on the basis of different colors of the insulation layers.

13. The method as claimed in claim 12, wherein the preparation of a micro section of the circuit carrier comprises:
exposing a cross-sectional surface, in particular a full cross section of the circuit carrier, and
preparing the cross-sectional surface to ascertain the number of insulation layers.

14. The method as claimed in claim 12, wherein to ascertain the number of insulation layers in the circuit carrier, the circuit carrier or at least one insulation layer of the circuit carrier is colored.

15. The method as claimed in claim 14, wherein the coloration takes place before or after the preparation of the cross section or micro section.

16. The method as claimed in claim 13, wherein to ascertain the number of insulation layers in the circuit carrier, the circuit carrier or at least one insulation layer of the circuit carrier is colored.

17. The method as claimed in claim 9, wherein the coloration takes place in such a way that the two insulation layers are recognizable as two distinct insulation layers at least in a cross section, in particular a micro section, of the circuit carrier due to their different colors.
